(19) United States
(12) Patent Application Publication
(10) Pub. No.: US 2026/0096168 A1
(43) Pub. Date: Apr. 2, 2026

(54) SUBSTRATE FOR FORMING SEMICONDUCTOR DEVICE, SEMICONDUCTOR LAMINATED STRUCTURE, SEMICONDUCTOR DEVICE, METHOD FOR MANUFACTURING SUBSTRATE FOR FORMING SEMICONDUCTOR DEVICE, METHOD FOR MANUFACTURING SEMICONDUCTOR LAMINATED STRUCTURE, AND METHOD FOR MANUFACTURING SEMICONDUCTOR DEVICE

(71) Applicant: UNIVERSITY PUBLIC CORPORATION OSAKA, Osaka (JP)

(72) Inventors: Naoteru Shigekawa, Osaka (JP); Jianbo Liang, Osaka (JP)

(21) Appl. No.: 19/110,797

(22) PCT Filed: Sep. 12, 2023
(86) PCT No.: PCT/JP2023/033217

§ 371 Date: Mar. 11, 2025

(30) Foreign Application Priority Data
Sep. 12, 2022 (JP) 2022-144364

(51) Int. Cl. H10D 62/832; H10D 62/83; H10P 14/20

(52) U.S. Cl. CPC H10D 62/8325; H10D 62/8303; H10P 14/2903; H10P 14/3208

(57) ABSTRACT

A substrate (1) for a semiconductor device of the present invention includes a diamond substrate (10) and a silicon carbide layer (20) located on a part or all of one surface (10a) of the diamond substrate (10), wherein the silicon carbide layer (20) has a thickness of 20 nm or less, and wherein a surface (20a) of the silicon carbide layer (20) has an arithmetic mean roughness Ra of 0.5 nm or less.

### TECHNICAL FIELD

The present invention relates to a substrate for a semiconductor device, a semiconductor laminated structure, a semiconductor device, a method for manufacturing a substrate for a semiconductor device, a method for manufacturing a semiconductor laminated structure, and a method for manufacturing a semiconductor device.

Priority is claimed on Japanese Patent Application No. 2022-144364, filed Sep. 12, 2022, the content of which is incorporated herein by reference.

### BACKGROUND ART

In recent years, there is a demand for substrates for semiconductor devices with high thermal conductivity as semiconductor devices (semiconductor equipment) become more powerful, faster, and more highly integrated. Diamond substrates, which have a high thermal conductivity of 500 W/mK or more, have been attracting attention as the substrates for forming semiconductor devices. Generally, since the surface of the diamond substrate is rough, there is a problem that the surface cannot be easily bonded to a semiconductor layer.

For addressing this problem, for example, Non-Patent Document 1 proposes a semiconductor laminated structure in which a thin silicon film is deposited on both of a surface of a diamond substrate and a surface of gallium nitride, and these surfaces are bonded to each other through silicon to thereby bond the diamond substrate and gallium nitride.

For example, Non-Patent Document 2 proposes a semiconductor laminated structure in which a gallium nitride element is produced on a silicon carbide substrate, the silicon carbide substrate is cut to reduce its thickness to 50 μm, and the silicon carbide substrate is bonded to a diamond substrate via a thin titanium film.

For example, Patent Document 1 proposes a semiconductor device in which a silicon carbide substrate implanted with hydrogen ions is bonded to a diamond substrate, the silicon carbide substrate is smart-cut by heat treatment, and crystals of gallium nitride are grown on the thinned silicon carbide substrate.

### CITATION LIST

### Non-Patent Documents

Non Patent Document 1: Z. Cheng, et al., “Interfacial Thermal Conductance across Room-Temperature Bonded GaN-Diamond Interfaces for GaN-on-Diamond Devices,”ACS Appl. Mater. Interfaces 12, pp. 8376-8384 (2020).

Non Patent Document 2: Yuichi Minoura, et al., “Surface activated bonding of SiC/diamond for thermal management of high-output power GaN HEMTs,” Jpn. J. Appl. Phys. 59, SGGD03 (2020).

### Patent Document

Patent Document 1: Japanese Unexamined Patent Application, First Publication No. 2016-139655

### SUMMARY OF INVENTION

### Technical Problem

However, when the semiconductor laminated structure of Non-Patent Document 1 is subjected to heat treatment at a high temperature of 800° C. or higher, a reaction called melt-back occurs at the interface between the gallium nitride and silicon, and voids are formed, so that a problem arises in that reliability is reduced when a semiconductor element (semiconductor device) is formed.

In the semiconductor laminated structure of Non-Patent Document 2, the silicon carbide substrate and the diamond substrate are bonded via the thin titanium film, but there is a problem that titanium has lower thermal conductivity than silicon carbide and inferior heat dissipation.

In the semiconductor device of Patent Document 1, it is unclear whether gallium nitride can be grown as crystals on the silicon carbide substrate after smart-cut.

Furthermore, there is a problem that the silicon carbide substrate is thick and has poor heat dissipation.

Therefore, an object of the present invention is to provide a substrate for a semiconductor device, a semiconductor laminated structure, and a semiconductor device capable of easily bonding a diamond substrate and a semiconductor layer and having excellent heat dissipation and heat resistance and a method for manufacturing these.

### Solution to Problem

The present invention has the following aspects.
[1] A substrate for a semiconductor device, including:
   a diamond substrate; and
   a silicon carbide layer located on a part or all of one surface of the diamond substrate,
   wherein the silicon carbide layer has a thickness of 20 nm or less, and
   wherein a surface of the silicon carbide layer has an arithmetic mean roughness Ra of 0.5 nm or less.
[2] The substrate for a semiconductor device according to [1],
   wherein a part or all of silicon carbide contained in the silicon carbide layer is amorphous.
[3] A semiconductor laminated structure including:
   a diamond substrate;
   a semiconductor layer located on a part or all of one surface of the diamond substrate; and
   a silicon carbide layer located between the diamond substrate and the semiconductor layer,
   wherein the semiconductor layer contains a nitride or an oxide,
   wherein the silicon carbide layer is a single layer, and
   wherein the silicon carbide layer has a thickness of 20 nm or less.
[4] The semiconductor laminated structure according to [3],
   wherein the silicon carbide layer has an arithmetic mean roughness Ra of 0.5 nm or less on its surface at an interface between the silicon carbide layer and the semiconductor layer.
[5] The semiconductor laminated structure according to [3] or [4],
   wherein a part or all of silicon carbide contained in the silicon carbide layer is amorphous.
[6] A semiconductor device including:
   the semiconductor laminated structure according to any one of [3] to [5],
   wherein a part or all of silicon carbide contained in the silicon carbide layer is polycrystalline.
[7] A method for manufacturing a substrate forming a semiconductor device including:
   depositing silicon carbide on a part or all of one surface of a diamond substrate to form a silicon carbide layer having a thickness of 20 nm or less and a surface having an arithmetic mean roughness Ra of 0.5 nm or less.
[8] A method for manufacturing a semiconductor laminated structure including:
   manufacturing a substrate for a semiconductor device by the method of [7]; and
   bonding a surface of the silicon carbide layer to a semiconductor layer containing a nitride or an oxide.
[9] A method for manufacturing a semiconductor device including:
   manufacturing a semiconductor laminated structure by the method of [8]; and
   performing heat treatment on the semiconductor laminated structure at 800° C. or higher.

### Advantageous Effects of Invention

According to the substrate for a semiconductor device, the semiconductor laminated structure, the semiconductor device, and the method for manufacturing these of the present invention, the diamond substrate and the semiconductor layer can be easily bonded, and the heat dissipation and heat resistance are excellent.

### BRIEF DESCRIPTION OF DRAWINGS

FIG. 1 A cross-sectional view of a substrate for a semiconductor device according to an embodiment of the present invention.

FIG. 2 A cross-sectional view of a semiconductor laminated structure according to an embodiment of the present invention.

FIG. 3 A cross-sectional view of a semiconductor device according to an embodiment of the present invention.

FIG. 4 A flowchart showing a part of a method for manufacturing a semiconductor device according to an embodiment of the present invention.

FIG. 5 A flowchart showing a part of a method for manufacturing a semiconductor device according to an embodiment of the present invention.

FIG. 6 A flowchart showing a part of a method for manufacturing a semiconductor device according to an embodiment of the present invention.

FIG. 7 A transmission electron microscope (TEM) photograph of a cross section of a semiconductor laminated structure according to an embodiment of the present invention before heat treatment.

FIG. 8 A TEM photograph of a cross section of a semiconductor laminated structure according to an embodiment of the present invention after heat treatment.

### DESCRIPTION OF EMBODIMENTS

### Substrate for Semiconductor Device

The substrate for a semiconductor device of the present invention includes a diamond substrate and a silicon carbide layer located on a part or all of one surface of the diamond substrate.

Hereinbelow, a substrate for a semiconductor device according to an embodiment of the present invention is described with reference to the drawings.

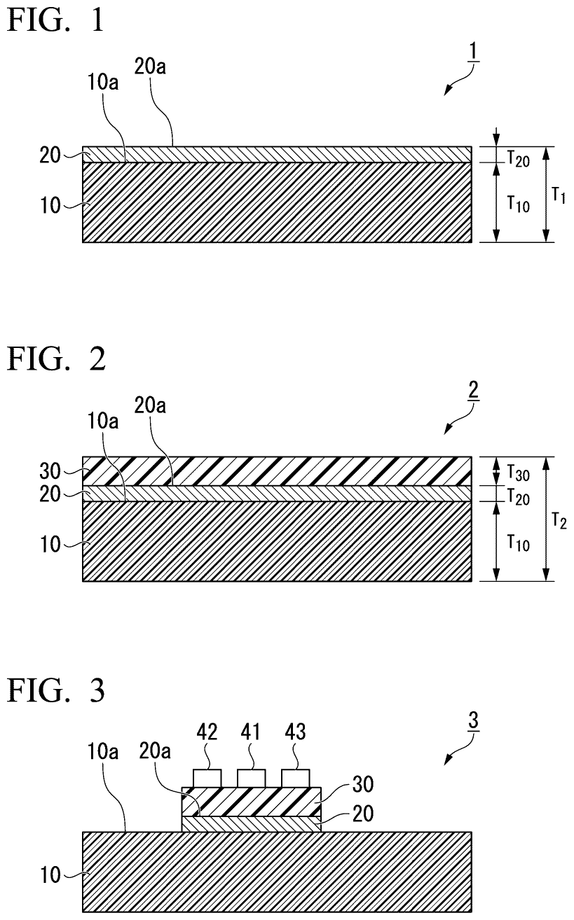

As shown in FIG. 1, a substrate 1 for a semiconductor device includes a diamond substrate 10 and a silicon carbide layer 20 located on one surface 10a of the diamond substrate 10.

The thickness T₁ of the substrate 1 for a semiconductor device is, for example, preferably 1 to 500 82 m, more preferably 10 to 400 μm, and even more preferably 50 to 300 μm. When the thickness T₁ is equal to or larger than the lower limit value, the physical strength of the semiconductor device can be further increased. When the thickness T₁ is equal to or smaller than the upper limit value, the size of the semiconductor device can be made more compact.

The thickness T₁ can be measured, for example, by a digital caliper or the like.

In this specification, the “thickness T₁” refers to the arithmetic mean value of thicknesses at 10 randomly selected locations.

The thickness T₁₀ of the diamond substrate 10 is, for example, preferably 10 to 500 μm, more preferably 30 to 400 μm, and even more preferably 50 to 300 μm. When the thickness T₁₀ is equal to or larger than the lower limit value, the physical strength of the semiconductor device can be further increased. When the thickness T₁₀ is equal to or smaller than the upper limit value, the size of the semiconductor device can be made more compact.

The thickness T₁₀ can be measured, for example, by a digital caliper or the like.

In this specification, the “thickness T₁₀” refers to the arithmetic mean value of thicknesses at 10 randomly selected locations.

The diamond substrate 10 has high thermal conductivity, and the semiconductor device including the diamond substrate 10 can have improved heat dissipation.

The thermal conductivity of the diamond substrate 10 is, for example, preferably 500 W/m·K or more, more preferably 700 W/m·K or more, and even more preferably 1000 W/m·K or more. When the thermal conductivity of the diamond substrate 10 is equal to or larger than the lower limit value, the heat dissipation of the semiconductor device can be further improved. The upper limit value of the thermal conductivity of the diamond substrate 10 is not particularly limited, and is set to, for example, 3000 W/m·K. The thermal conductivity of the diamond substrate 10 is preferably 500 to 3000 W/m·K, more preferably 700 to 3000 W/m·K, and even more preferably 1000 to 3000 W/m·K.

The thermal conductivity of the diamond substrate 10 can be measured by, for example, a temperature gradient method, a disk heat flow meter method, or the like.

The thermal conductivity of the diamond substrate 10 can be adjusted by the purity, crystallinity, crystal type, density, or a combination thereof with respect to the diamond in the diamond substrate 10.

The thickness T₂₀ of the silicon carbide layer 20 is 20 nm or less, preferably 1 nm or more and 18 nm or less, more preferably 2 nm or more and 16 nm or less, and even more preferably 5 nm or more and 15 nm or less. When the thickness T₂₀ is equal to or larger than the lower limit value, the arithmetic mean roughness Ra of the surface 20a of the silicon carbide layer 20 can be further reduced. When the thickness T₂₀ is equal to or smaller than the upper limit value, the heat dissipation of the semiconductor device can be further improved.

The thickness T₂₀ can be determined, for example, by observing a cross section of the substrate 1 for a semiconductor device in the thickness direction with an electron microscope or the like. As the electron microscope, for example, a transmission electron microscope (TEM) can be used.

In this specification, “thickness T₂₀” refers to the arithmetic mean value of thicknesses at 10 randomly selected locations.

The silicon carbide layer 20 has a higher thermal conductivity than a layer made of silicon alone. Therefore, the semiconductor device including the silicon carbide layer 20 has improved heat dissipation compared to the semiconductor device including the layer of elemental silicon of the same thickness.

The thermal conductivity of the silicon carbide layer 20 is, for example, preferably 100 W/m·K or more, more preferably 150 W m·K or more, and even more preferably 200 W/m·K or more. When the thermal conductivity of the silicon carbide layer 20 is equal to or higher than the lower limit value, the heat dissipation of the semiconductor device can be further improved. The upper limit value of the thermal conductivity of the silicon carbide layer 20 is not particularly limited, but is set to, for example, 450 W/m·K. The thermal conductivity of the silicon carbide layer 20 is preferably 100 to 450 W/m·K, more preferably 150 to 450 W/m·K, and even more preferably 200 to 450 W/M·K.

The thermal conductivity of the silicon carbide layer 20 can be measured by, for example, a temperature gradient method, a disk heat flow meter method, or the like.

The thermal conductivity of the silicon carbide layer 20 can be adjusted by the purity, crystallinity, crystal type, density, or a combination thereof with respect to the silicon carbide in the silicon carbide layer 20.

The arithmetic mean roughness Ra of the surface 20a of the silicon carbide layer 20 is 0.5 nm or less, preferably 0.45 nm or less, and more preferably 0.4 nm or less. When the arithmetic mean roughness Ra of the surface 20a of the silicon carbide layer 20 is equal to or smaller than the upper limit value, the bondability with the semiconductor layer in the semiconductor laminated structure described later can be further improved. Therefore, the heat dissipation and heat resistance of the semiconductor device can be further improved. The lower limit value of the arithmetic mean roughness Ra of the surface 20a of the silicon carbide layer 20 is not particularly limited and is set to, for example, 0.01 nm. The arithmetic mean roughness Ra of the surface 20a of the silicon carbide layer 20 is preferably 0.01 to 0.5 nm, more preferably 0.01 to 0.45 nm, and even more preferably 0.01 to 0.4 nm.

The arithmetic mean roughness Ra of the surface 20a of the silicon carbide layer 20 can be determined, for example, by analysis using an atomic force microscope (AFM). The measurement conditions for the atomic force microscope (AFM) can be the same as those described in Examples below.

It is preferable that a part or all of the silicon carbide contained in the silicon carbide layer 20 is amorphous. When silicon carbide is amorphous, the arithmetic mean roughness Ra of the surface 20a of the silicon carbide layer 20 can be further reduced.

Whether silicon carbide is amorphous or not can be determined by observing a cross section of the substrate 1 for a semiconductor device in the thickness direction with an electron microscope or the like. For example, when no striped structure is observed in the silicon carbide layer 20 of the substrate 1 for a semiconductor device, and the silicon carbide does not correspond to any of cubic crystals, hexagonal crystals, and rhombohedral crystals, then, it is determined that “at least a part of the silicon carbide contained in the silicon carbide layer 20 is amorphous.” As the electron microscope, for example, a transmission electron microscope (TEM) can be used.

### Semiconductor Laminated Structure

The semiconductor laminated structure of the present invention includes a diamond substrate, a semiconductor layer located on a part or all of one surface of the diamond substrate, and a silicon carbide layer located between the diamond substrate and the semiconductor layer.

The semiconductor layer contains a nitride or an oxide, the silicon carbide layer is a single layer, and the thickness of the silicon carbide layer is 20 nm or less.

Hereinbelow, a semiconductor laminated structure according to an embodiment of the present invention is described with reference to the drawings.

As shown in FIG. 2, a semiconductor laminated structure 2 includes the diamond substrate 10, the silicon carbide layer 20 located on one surface 10a of the diamond substrate 10, and a semiconductor layer 30 located on a surface 20a of the silicon carbide layer 20. That is, the semiconductor laminated structure 2 includes the diamond substrate 10, the semiconductor layer 30 located on one surface 10a of the diamond substrate 10, and the silicon carbide layer 20 located between the diamond substrate 10 and the semiconductor layer 30.

Hereinbelow, the same components as those in FIG. 1 are denoted by the same reference numerals, and the descriptions therefor are omitted.

The thickness T₂ of the semiconductor laminated structure 2 is, for example, preferably 2 to 1000 μm, more preferably 5 to 700 μm, and even more preferably 10 to 500 μm. When the thickness T₂ is equal to or larger than the lower limit value, the physical strength of the semiconductor device can be further increased. When the thickness T₂ is equal to or smaller than the upper limit value, the size of the semiconductor device can be made more compact.

The thickness T₂ can be measured, for example, by a digital caliper or the like.

In this specification, the “thickness T₂” is the arithmetic mean value of thicknesses at 10 randomly selected locations.

The arithmetic mean roughness Ra of surface 20a of silicon carbide layer 20 at the interface between silicon carbide layer 20 and semiconductor layer 30 is preferably 0.5 nm or less, more preferably 0.45 nm or less, and even more preferably 0.4 nm or less. When the arithmetic mean roughness Ra of the surface 20a of the silicon carbide layer 20 is equal to or smaller than the upper limit value, the bondability with the semiconductor layer 30 can be further improved. Therefore, the heat dissipation and heat resistance of the semiconductor device can be further improved. The lower limit value of the arithmetic mean roughness Ra of the surface 20a of the silicon carbide layer 20 is not particularly limited and is set to, for example, 0.01 nm. The arithmetic mean roughness Ra of the surface 20a of the silicon carbide layer 20 is preferably 0.01 to 0.5 nm, more preferably 0.01 to 0.45 nm, and even more preferably 0.01 to 0.4 nm.

The arithmetic mean roughness Ra of the surface 20a of the silicon carbide layer 20 can be determined, for example, by removing the semiconductor layer 30 and then analyzing the surface using an atomic force microscope (AFM). The measurement conditions for the atomic force microscope (AFM) may be the same as those described in Examples below.

The silicon carbide layer 20 is a single layer. Here, the “single layer” refers to a single layer formed in one process, which does not contain a bonding interface therein, and which may contain amorphous silicon carbide and be formed in layers or stripes.

Whether the silicon carbide layer 20 is a single layer can be determined, for example, by observing a cross section of the semiconductor laminated structure 2 in the thickness direction using a transmission electron microscope (TEM) and performing element distribution analysis using energy dispersive X-ray spectroscopy (EDX) associated with the TEM. When the silicon carbide layer 20 is not a single layer, a boundary line (bonding interface) parallel to the boundary surface between the silicon carbide layer 20 and the semiconductor layer 30 can be identified within the silicon carbide layer-silicon carbide layer, and an element derived from the bond (for example, iron) can be detected at that position.

By forming the silicon carbide layer 20 as a single layer, a silicon carbide layer is formed on each of the bonding surfaces of the diamond substrate 10 and the semiconductor layer 30, and the semiconductor laminated structure 2 is materialized with a smaller number of bonding interfaces than when these silicon carbide layers are bonded together. As a result, the thermal resistance caused by the bonding interface can be reduced, and the heat dissipation and heat resistance can be improved.

The semiconductor layer 30 contains a nitride or an oxide. Examples of nitrides include gallium nitride (GaN), indium nitride (InN), aluminum nitride (AIN), and mixed crystals thereof. The semiconductor layer 30 may be a multi-layer structure made of these nitrides.

Examples of oxides include gallium oxide (Ga₂O₃), aluminum oxide (Al₂O₃), and mixed crystals thereof. The semiconductor layer 30 may be a multi-layer structure made of these oxides.

The thickness T₃₀ of the semiconductor layer 30 is, for example, preferably 0.1 to 50 μm, more preferably 0.2 to 20 μm, and even more preferably 0.5 to 10 μm. When the thickness T₃₀ is equal to or larger than the lower limit value, the output of the semiconductor device can be further increased. When the thickness T₃₀ is equal to or smaller than the upper limit value, the temperature rise of the semiconductor device due to the thermal resistivity of the nitride or oxide contained in the semiconductor layer 30 is suppressed, and the bondability with the diamond substrate 10 is further improved. Therefore, the heat dissipation and heat resistance of the semiconductor device can be further improved.

The thickness T₃₀ can be determined, for example, by observing a cross section of the semiconductor laminated structure 2 in the thickness direction with an electron microscope or the like. As the electron microscope, for example, a transmission electron microscope (TEM) can be used.

In this specification, the “thickness T₃₀” refers to the arithmetic mean value of thicknesses at 10 randomly selected locations.

### Semiconductor Device

The semiconductor device of the present invention includes the semiconductor laminated structure of the present invention, and a part or all of the silicon carbide contained in the silicon carbide layer is polycrystalline.

Hereinbelow, the semiconductor device according to an embodiment of the present invention is described with reference to the drawings.

As shown in FIG. 3, a semiconductor device 3 includes the diamond substrate 10, the semiconductor layer 30 located on a part of one surface 10a of the diamond substrate 10, and the silicon carbide layer 20 located between the diamond substrate 10 and the semiconductor layer 30.

In the semiconductor device 3, a part of the semiconductor layer 30 and the silicon carbide layer 20 of the semiconductor laminated structure 2 are removed. A gate electrode 41, a source electrode 42, and a drain electrode 43 are formed on the surface of the semiconductor layer 30 in the silicon carbide layer 20 and the semiconductor layer 30 remaining on the diamond substrate 10.

Hereinbelow, the same components as those in FIG. 2 are denoted by the same reference numerals, and the descriptions therefor are omitted.

The gate electrode 41 can be made of a known material. Examples of materials forming the gate electrode 41 include nickel, gold, and palladium.

The source electrode 42 can be made of a known material. Examples of materials forming the source electrode 42 include titanium, aluminum, nickel, gold, and multi-layer structures thereof.

The drain electrode 43 can be made of a known material. Examples of materials forming the drain electrode 43 include titanium, aluminum, nickel, gold, and multi-layer structures thereof.

The thickness of the gate electrode 41 is, for example, preferably 0.1 to 20 μm, more preferably 0.5 to 15 μm, and even more preferably 1 to 10 μm. When the thickness of the gate electrode 41 is equal to or larger than the lower limit value, the output of the semiconductor device 3 can be further increased. When the thickness of the gate electrode 41 is equal to or smaller than the upper limit value, the gate electrode 41 can be miniaturized, and the operating frequency of the semiconductor device 3 can be improved. In addition, when the thickness of the gate electrode 41 is equal to or smaller than the upper limit value, the production efficiency of the semiconductor device 3 can be further improved.

The thickness of the source electrode 42 is the same as the thickness of the gate electrode 41.

The thickness of the drain electrode 43 is the same as the thickness of the gate electrode 41.

The thickness of the electrode can be measured, for example, by a digital caliper or the like. The thickness of the electrode is defined as the arithmetic mean value of the thicknesses at 10 randomly selected locations.

The patterns of the gate electrode 41, the source electrode 42, and the drain electrode 43 are not particularly limited, and can be appropriately determined depending on the application of the semiconductor device 3.

In the semiconductor laminated structure 2, the shape of the pattern of the semiconductor layer 30 and the silicon carbide layer 20 to be removed is not particularly limited, and can be appropriately determined depending on the application of the semiconductor device 3 and the like.

In the semiconductor device 3, a part or all of the silicon carbide contained in the silicon carbide layer 20 is polycrystalline.

When silicon carbide is polycrystalline, the bonding strength between the silicon carbide layer 20 and the semiconductor layer 30 can be further increased. Therefore, the heat dissipation and heat resistance of the semiconductor device 3 can be further improved.

Whether or not silicon carbide is polycrystalline can be determined by observing a cross section of the semiconductor device 3 in the thickness direction with an electron microscope or the like. For example, when a striped structure is observed in a part of a silicon carbide layer, it means that the atoms in this part are arranged periodically, that is, the part is crystallized. In this way, when a striped structure is observed in at least a part of the silicon carbide layer, it is determined that “at least a part of the silicon carbide contained in the silicon carbide layer 20 is polycrystalline.” As the electron microscope, for example, a transmission electron microscope (TEM) can be used.

### Method for Manufacturing Substrate for Semiconductor Device

The method for manufacturing a substrate for a semiconductor device of the present invention includes depositing silicon carbide on a part or all of one surface of a diamond substrate to form a silicon carbide layer having a thickness of 20 nm or less and a surface having an arithmetic mean roughness Ra of 0.5 nm or less.

The deposition step is a step of depositing silicon carbide on a part or all of one surface of a diamond substrate to form a silicon carbide layer having a thickness of 20 nm or less and an arithmetic mean surface roughness Ra of 0.5 nm or less.

Methods of depositing silicon carbide include, for example, sputtering, vacuum deposition, chemical vapor deposition, and physical vapor deposition.

The preferred method for depositing silicon carbide is sputtering in that the thickness of the silicon carbide layer can be uniform and thin.

Examples of the sputtering method include a two-pole method, a magnetron method, reactive sputtering, ion beam sputtering, and electron cyclotron resonance (ECR) sputtering. As the sputtering method, the magnetron method is preferred in that silicon carbide can be stably deposited and an arithmetic mean roughness Ra of the surface of 0.5 nm or less can be easily achieved.

### Method for Manufacturing Semiconductor Laminated Structure

The method for manufacturing a semiconductor laminated structure for the present invention includes manufacturing a substrate for a semiconductor device by the method of the present invention and bonding a surface of the silicon carbide layer to a semiconductor layer containing a nitride or an oxide.

The process for manufacturing the substrate for a semiconductor device is the same as that of the above-mentioned method for manufacturing a substrate for a semiconductor device.

The bonding step is a step of bonding the surface of the silicon carbide layer to the semiconductor layer containing a nitride or an oxide after the step of manufacturing the substrate for a semiconductor device.

Methods of bonding the silicon carbide layer and the semiconductor layer include, for example, surface activated bonding (SAB), high pressure bonding, and high vacuum bonding.

The SAB method is a method in which the surfaces to be bonded are cleaned with a chemical solution and pure water, activated with plasma or ions in a vacuum chamber, and then bonded in a low-temperature atmosphere ranging from room temperature (for example, 25° C.) to 400° C.

In the high pressure bonding method, the surfaces to be bonded are cleaned with a chemical solution and pure water, and then bonded by applying a high pressure of 0.1 MPa to 10 MPa while being heated in the atmosphere.

In the high vacuum bonding method, the surfaces to be bonded are cleaned with a chemical solution and pure water, and then bonded in a high vacuum atmosphere of about 10⁻⁶ Pa to 10⁻³ Pa.

As the method for bonding the silicon carbide layer and the semiconductor layer, surface activated bonding is preferred in that bonding at room temperature (for example, 5 to 30° C.) and easier bonding are possible.

The temperature in the bonding step (bonding temperature) is, for example, preferably 0 to 400° C., more preferably 0 to 100° C., and even more preferably 5 to 30° C. (room temperature) from the viewpoint of suppressing deterioration of the silicon carbide layer and the semiconductor layer.

### Method for Manufacturing Semiconductor Device

The method for manufacturing a semiconductor device of the present invention includes manufacturing the semiconductor laminated structure by the above-mentioned method for manufacturing a semiconductor laminated structure for the present invention and performing heat treatment on the semiconductor laminated structure at 800° C. or higher.

Hereinbelow, the method for manufacturing a semiconductor device of the embodiment is described with reference to the drawings.

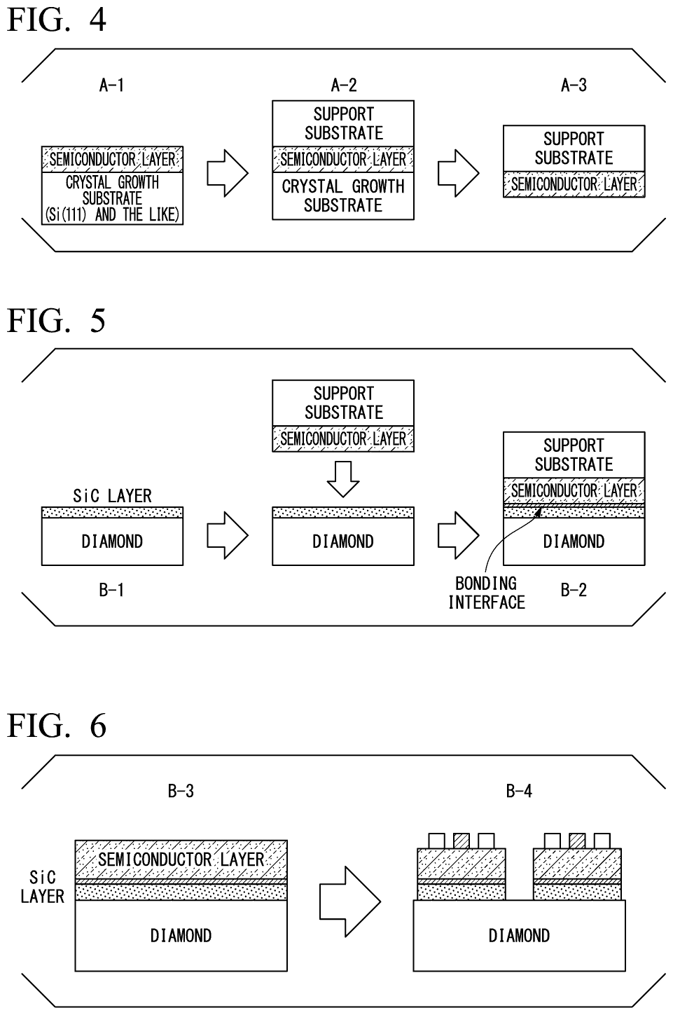

As shown in FIGS. 4 to 6, the method for manufacturing a semiconductor device of the embodiment includes steps A-1, A-2, A-3, B-1, B-2, B-3, and B-4.

As shown in FIG. 4, step A-1 is a step of growing a nitride or an oxide on a crystal growth substrate to form a semiconductor layer, thereby obtaining a first laminate.

Examples of the crystal growth substrate include a silicon substrate, a silicon carbide substrate, and a sapphire substrate, with the silicon substrate being preferred from the standpoint of cost.

Examples of the crystal growth method include metal organic chemical vapor deposition (MOCVD), molecular beam epitaxy (MBE), hydride vapor phase epitaxy (HVPE), sublimation, and flux methods. As the crystal growth method, MOCVD is preferred from the viewpoint of crystal quality.

Step A-2 is a step of bonding the surface of the semiconductor layer of the first laminate to a support substrate to obtain a second laminate.

The support substrate is not particularly limited as long as the support substrate is suitable for supporting the semiconductor layer until the crystal growth substrate is removed from the semiconductor layer and a silicon carbide layer is bonded to the semiconductor layer in the subsequent process. Examples of the support substrate include a silicon substrate, a silicon carbide substrate, a molybdenum substrate, and a glass substrate.

The method for bonding the semiconductor layer and the support substrate is not particularly limited, and from the viewpoints of easy attachment and detachment and sufficient support of the semiconductor layer, adhesion with wax, brazing material, solder, or the like is preferred.

Step A-3 is a step of removing the crystal growth substrate from the second laminate obtained in step A-2, and polishing the back surface of the semiconductor layer to obtain a third laminate.

The method for removing the crystal growth substrate is not particularly limited, and examples thereof include cutting, grinding, polishing, etching, and the like.

The back surface of the semiconductor layer can be polished by, for example, chemical mechanical polishing (CMP) or the like.

As shown in FIG. 5, step B-1 is a step of depositing silicon carbide on a diamond substrate to form a silicon carbide layer, thereby obtaining a fourth laminate (semiconductor device forming substrate).

Examples of method for depositing silicon carbide on a diamond substrate include sputtering, vacuum deposition, chemical vapor deposition, and physical vapor deposition. The preferred method for depositing silicon carbide is sputtering in that the thickness of the silicon carbide layer is uniform and thin.

Step B-2 is a step of bonding the semiconductor layer of the third laminate obtained in step A-3 to the silicon carbide layer of the fourth laminate obtained in step B-1 to obtain a fifth laminate.

Examples of method for bonding the semiconductor layer of the third laminate and the silicon carbide layer of the fourth laminate include a SAB method, a high pressure bonding method, and a high vacuum bonding method. The method for bonding the semiconductor layer of the third laminate and the silicon carbide layer of the fourth laminate is preferably the SAB method in that bonding at room temperature and easy bonding are possible.

As shown in FIG. 6, step B-3 is a step of removing the support substrate from the fifth laminate obtained in step B-2 to obtain a sixth laminate (semiconductor laminated structure).

Examples of method for removing the support substrate from the fifth laminate include detachment, separation, grinding, polishing, and etching.

Step B-4 is a step of subjecting the sixth laminate to a process including a mesa formation process and heat treatment to impart an element structure to the semiconductor layer. In this context, the element structure refers to a structure having a buffer layer, a channel layer, a barrier layer, and a contact layer from the side closer to the silicon carbide layer.

The heating temperature during the heat treatment is, for example, preferably 800° C. or higher, more preferably 850° C. or higher, and even more preferably 900° C. or higher. When the heating temperature is equal to or higher than the lower limit value, the semiconductor layer can be sufficiently provided with an element structure. The upper limit value of the heating temperature is not particularly limited, but is set to, for example, 1200° C. from the viewpoint of suppressing deterioration of the semiconductor layer. The heating temperature in the heat treatment is preferably 800 to 1200° C., more preferably 850 to 1200° C., and even more preferably 900 to 1200° C.

By subjecting the sixth laminate to heat treatment, polycrystallization of silicon carbide contained in the silicon carbide layer of the sixth stack is facilitated. When silicon carbide is polycrystalline, the bonding strength between the silicon carbide layer and the semiconductor layer can be further increased. Therefore, the heat dissipation and heat resistance of the semiconductor device can be further improved.

After the sixth laminate is subjected to heat treatment, the laminate is subjected to lithography to process the silicon carbide layer and the semiconductor layer on the diamond substrate to form a desired pattern, and then a gate electrode, a source electrode, and a drain electrode are laminated to obtain a semiconductor element (semiconductor device).

The gate electrode, source electrode, and drain electrode may be made of a known metal such as nickel, gold, titanium, aluminum, palladium, or a multi-layer structure thereof.

The gate electrode, source electrode, and drain electrode are obtained by forming a metal laminate film by film formation such as vacuum deposition.

When forming the source electrode and the drain electrode, heat treatment is performed after the formation of the metal laminate film to react with the nitride or oxide contained in the semiconductor layer. The heating temperature for this purpose is, for example, preferably 650° C. or higher, more preferably 700° C. or higher, and even more preferably 800° C. or higher.

The implementation of the above steps results in the production of a semiconductor element (semiconductor device) in which the silicon carbide layer located on the surface of the diamond substrate is bonded to the semiconductor layer and the gate electrode, source electrode, and drain electrode are formed on the surface of the semiconductor layer.

### EXAMPLES

The present invention will be described in more detail below using examples, but the present invention is not limited to these examples.

A rectangular diamond substrate having a length of 4 mm, a width of 4 mm, and a thickness of 350 μm was prepared. When one surface of this diamond substrate was analyzed using an atomic force microscope (AFM), the arithmetic mean roughness Ra was found to be 0.77 nm. Silicon carbide was deposited on one surface of this diamond substrate by sputtering to form a silicon carbide layer having a thickness of 13 nm, thereby obtaining a fourth laminate (step B-1).

When the surface of the silicon carbide layer of the fourth laminate was analyzed using an AFM, the arithmetic mean roughness Ra was found to be 0.37 nm. The measurement conditions for the arithmetic mean roughness Ra are as follows.
Measuring device: SPM-9600 (Shimadzu Corporation)
Measuring Probe: Nchr (nanoworld)
Measuring range: 1 μm²

Next, a silicon substrate having a diameter of 4 inches (101.6 mm) and a thickness of 500 μm was prepared as a crystal growth substrate, and gallium nitride was grown as a nitride on one surface of the silicon substrate by MOCVD to form a semiconductor layer having a thickness of 1 μm, thereby obtaining a first laminate (step A-1). Next, the semiconductor layer of the first laminate was cut into a rectangle having a length of 10 mm and a width of 12 mm. A rectangular silicon substrate having a length of 20 mm, a width of 20 mm, and a thickness of 500 μm was attached as a support substrate with wax to obtain a second laminate (step A-2). Next, the crystal growth substrate of the second laminate was removed by etching with a hydrofluoric acid-nitric acid mixture, and the back surface of the semiconductor layer was polished by CMP to obtain a third laminate (step A-3).

Next, the semiconductor layer of the third laminate and the silicon carbide layer of the fourth laminate were bonded by the SAB method to obtain a fifth laminate (step B-2). The support substrate of the obtained fifth laminate was removed by etching with a hydrofluoric acid-nitric acid mixture to obtain a sixth laminate (semiconductor laminated structure) (step B-3).

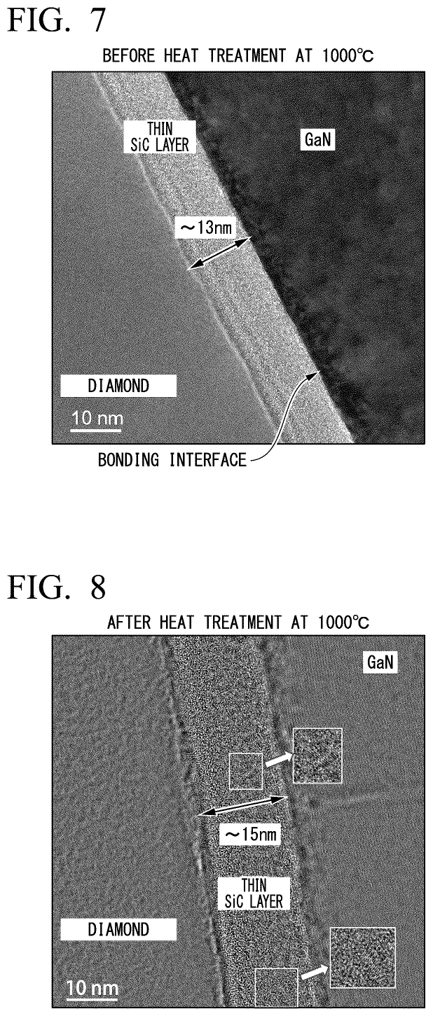

The cross section of the obtained sixth laminate in the thickness direction was observed by TEM. The results are shown in FIG. 7.

As shown in FIG. 7, it was confirmed that a thin layer of silicon carbide (thin SiC layer) with a thickness of 13 nm was formed between the diamond substrate and the semiconductor layer (gallium nitride, GaN). No striped structure was observed in the thin silicon carbide layer, and it was confirmed that at least a part of the silicon carbide contained in the silicon carbide layer was amorphous.

Next, the sixth laminate was subjected to heat treatment at 1000° C. for 3 minutes (step B-4). The cross section of the semiconductor laminated structure in the thickness direction after the heat treatment was observed by TEM. The results are shown in FIG. 8.

As shown in FIG. 8, a striped structure was observed in an image showing a part of the silicon carbide layer (thin SiC layer) enlarged 1.5 times, and it was confirmed that a part of the silicon carbide contained in the silicon carbide layer was polycrystalline.

Further, as shown in FIG. 8, it was confirmed that no melt-back occurred at the interface between the silicon carbide layer and the semiconductor layer, and the semiconductor laminated structure had sufficient heat resistance.

### REFERENCE SIGNS LIST

1 Substrate for semiconductor device
2 Semiconductor laminated structure
3 Semiconductor device
10 Diamond substrate
10a One surface of diamond substrate
20 Silicon carbide layer
20a Surface of silicon carbide layer
30 Semiconductor layer
41 Gate electrode
42 Source electrode
43 Drain electrode

1. A substrate for a semiconductor device, comprising:
a diamond substrate; and
a silicon carbide layer located on a part or all of one surface of the diamond substrate,
wherein the silicon carbide layer has a thickness of 20 nm or less,
wherein a surface of the silicon carbide layer has an arithmetic mean roughness Ra of 0.5 nm or less, and
wherein a part or all of silicon carbide contained in the silicon carbide layer is amorphous, which is confirmed by no presence of striped structure and no presence of silicon carbide as any of cubic crystals, hexagonal crystals, and rhombohedral crystals in a transmission electron microscope (TEM) observation of a cross section of the substrate for a semiconductor device in a thickness direction.

2. (canceled)

3. A semiconductor laminated structure comprising:
a diamond substrate;
a semiconductor layer located on a part or all of one surface of the diamond substrate; and
a silicon carbide layer located between the diamond substrate and the semiconductor layer,
wherein the semiconductor layer contains a nitride or an oxide,
wherein the silicon carbide layer is a single layer,
wherein the silicon carbide layer has a thickness of 20 nm or less, and
wherein a part or all of silicon carbide contained in the silicon carbide layer is amorphous, which is confirmed by no presence of striped structure and no presence of silicon carbide as any of cubic crystals, hexagonal crystals, and rhombohedral crystals in a transmission electron microscope (TEM) observation of a cross section of the semiconductor laminated structure in a thickness direction.

4. The semiconductor laminated structure according to claim 3,
wherein the silicon carbide layer has an arithmetic mean roughness Ra of 0.5 nm or less on its surface at an interface between the silicon carbide layer and the semiconductor layer.

5. (canceled)

6. A semiconductor device comprising:
the semiconductor laminated structure according to claim 3,
wherein a part of silicon carbide contained in the silicon carbide layer is polycrystalline.

7. A method for manufacturing a substrate for a semiconductor device, comprising:
depositing silicon carbide on a part or all of one surface of a diamond substrate to form a silicon carbide layer having a thickness of 20 nm or less and a surface having an arithmetic mean roughness Ra of 0.5 nm or less,
wherein a part or all of silicon carbide contained in the silicon carbide layer is amorphous, which is confirmed by no presence of striped structure and no presence of silicon carbide as any of cubic crystals, hexagonal crystals, and rhombohedral crystals in a transmission electron microscope (TEM) observation of a cross section of the substrate for a semiconductor device in a thickness direction.

8. A method for manufacturing a semiconductor laminated structure comprising:
manufacturing a substrate for a semiconductor device by the method of claim 7; and
bonding a surface of the silicon carbide layer to a semiconductor layer containing a nitride or an oxide.

9. A method for manufacturing a semiconductor device comprising:
manufacturing a semiconductor laminated structure by the method of claim 8; and
performing heat treatment on the semiconductor laminated structure at 800° C. or higher.

10. A semiconductor laminated structure comprising:
a diamond substrate;
a semiconductor layer located on a part or all of one surface of the diamond substrate; and
a silicon carbide layer located between the diamond substrate and the semiconductor layer,
wherein the semiconductor layer contains a nitride or an oxide,
wherein the silicon carbide layer has a thickness of 20 nm or less,
wherein the silicon carbide layer has an arithmetic mean roughness Ra of 0.5 nm or less on its surface, and
wherein the silicon carbide layer has a thermal conductivity of 100 to 450 W/m·K.

11. The semiconductor laminated structure according to claim 10, wherein the silicon carbide layer has a thermal conductivity of 200 to 450 W/m·K.

12. A semiconductor device comprising the semiconductor laminated structure of claim 10, wherein a part of silicon carbide contained in the silicon carbide layer is polycrystalline.
